(19) United States
(12) Patent Application Publication
(10) Pub. No.: US 2025/0169214 A1
(43) Pub. Date: May 22, 2025

(54) LIGHT DETECTION DEVICE, METHOD OF MANUFACTURING THE SAME, AND ELECTRONIC DEVICE

(71) Applicant: SONY SEMICONDUCTOR SOLUTIONS CORPORATION, KANAGAWA (JP)

(72) Inventor: YOSHIHIRO ANDO, KANAGAWA (JP)

(21) Appl. No.: 18/841,030

(22) PCT Filed: Feb. 17, 2023
(86) PCT No.: PCT/JP2023/005630

§ 371 Date: Aug. 23, 2024

(30) Foreign Application Priority Data
Mar. 4, 2022 (JP) 2022-033312

(51) Int. Cl. H10F 39/00; G02B 5/00

(52) U.S. Cl. CPC H10F 39/8053; G02B 5/008; H10F 39/024; H10F 39/8063

(57) ABSTRACT

Provided is a light detection device that suppresses light interference. The light detection device includes: a semiconductor layer having a photoelectric conversion unit; a first insulating film layered on a light incidence surface side of the semiconductor layer; an optical element having a metal film layered on the first insulating film and an opening array formed in a region, of the metal film, that overlaps with the photoelectric conversion unit in plan view, the optical element being capable of selecting a specific light; a second insulating film layered on the optical element; and a third insulating film layered on the second insulating film. One of a surface of the metal film on the second insulating film side thereof or a surface of the second insulating film on the third insulating film side thereof has unevenness that is greater than unevenness in a surface of the metal film on the first insulating film side thereof or a surface of the first insulating film on the semiconductor layer side thereof.

### TECHNICAL FIELD

The present technique (the technique according to the present disclosure) relates to a light detection device, a method of manufacturing the same, and an electronic device, and particularly relates to a light detection device including an optical element having a metal film, a method of manufacturing the same, and an electronic device.

### BACKGROUND ART

A technique has been proposed in which a filter which is microfabricated in a metal film and which transmits a specific wavelength, polarized light, and the like is applied to a solid-state image sensor or the like (e.g., PTL 1).

### Citation List

### Patent Literature

### [PTL 1]

WO 2018/030213

### SUMMARY

### Technical Problem

A filter such as that described above is constituted by a metal material and is therefore highly reflective. There have been cases where reflected light causes interference. An object of the present technique is to provide a light detection device which suppresses light interference, a method of manufacturing the same, and an electronic device.

### Solution to Problem

A light detection device according to one aspect of the present technique includes: a semiconductor layer having a photoelectric conversion unit; a first insulating film layered on a light incidence surface side of the semiconductor layer; an optical element having a metal film layered on the first insulating film and an opening array formed in a region, of the metal film, that overlaps with the photoelectric conversion unit in plan view, the optical element being capable of selecting a specific light; a second insulating film layered on the optical element; and a third insulating film layered on the second insulating film. One of a surface of the metal film on the second insulating film side thereof or a surface of the second insulating film on the third insulating film side thereof has unevenness that is greater than unevenness in a surface of the metal film on the first insulating film side thereof or a surface of the first insulating film on the semiconductor layer side thereof.

A method for manufacturing a light detection device according to one aspect of the present technique includes: preparing a substrate including a semiconductor layer in which a photoelectric conversion unit is provided and a first insulating film layered on a light incidence surface side of the semiconductor layer; layering a metal film on an exposed surface of the first insulating film; forming a hard mask pattern on an exposed surface of the metal film; forming a plurality of openings in the metal film by etching the metal film based on the hard mask pattern, to form an optical element having the metal film and an array of the openings; and layering a second insulating film to cover the hard mask pattern but not completely fill the openings.

An electronic device according to one aspect of the present technique includes the above-described light detection device and an optical system that forms an image of image light from a subject on the above-described light detection device.

### BRIEF DESCRIPTION OF DRAWINGS

FIG. 1 is a chip layout diagram illustrating one example of the configuration of a light detection device according to a first embodiment of the present technique.

FIG. 2 is a block diagram illustrating an example of the configuration of the light detection device according to the first embodiment of the present technique.

FIG. 3 is an equivalent circuit diagram illustrating a pixel in the light detection device according to the first embodiment of the present technique.

FIG. 4 is a longitudinal cross-sectional view illustrating the cross-sectional structure of the pixel in the light detection device according to the first embodiment of the present technique.

FIG. 5 is a lateral cross-sectional view illustrating the relative relationship between a plasmon filter and a photoelectric conversion unit when viewed in a cross-section taken along line A-A in FIG. 4.

FIG. 6 is a longitudinal cross-sectional view illustrating a part of the cross-section of the pixel illustrated in FIG. 4 in an enlarged manner.

FIG. 7 is a plan view of a wire grid polarizer included in a light detection device according to Variation 1 on the first embodiment of the present technique.

FIG. 8 is a longitudinal cross-sectional view illustrating the cross-sectional structure of the pixel in the light detection device according to a second embodiment of the present technique.

FIG. 9 is a plan view illustrating unevenness formed in a surface of an insulating film included in the light detection device according to the second embodiment of the present technique.

FIG. 10 is a plan view illustrating unevenness formed in a surface of an insulating film included in a light detection device according to Variation 1 on the second embodiment of the present technique.

FIG. 11 is a longitudinal cross-sectional view illustrating the cross-sectional structure of a pixel in a light detection device according to Variation 2 on a second embodiment of the present technique.

FIG. 12 is a longitudinal cross-sectional view illustrating the cross-sectional structure of a pixel in a light detection device according to Variation 3 on a second embodiment of the present technique.

FIG. 13 is a longitudinal cross-sectional view illustrating a part of the cross-section of the pixel illustrated in FIG. 12 in an enlarged manner.

FIG. 14A is a process cross-sectional view illustrating a method for manufacturing the light detection device according to Variation 3 on the second embodiment of the present technique.

FIG. 14B is a process cross-sectional view continuing from FIG. 14A.

FIG. 14C is a process cross-sectional view continuing from FIG. 14B.

FIG. 14D is a process cross-sectional view continuing from FIG. 14C.

FIG. 14E is a process cross-sectional view continuing from FIG. 14D.

FIG. 15 is a block diagram illustrating an example of the overall configuration of an electronic device.

### DESCRIPTION OF EMBODIMENTS

Preferred embodiments for carrying out the present technique will be described hereinafter with reference to the drawings. Note that the following embodiments describe examples of representative embodiments of the present technique, and the scope of the present technique should not be narrowly interpreted on the basis thereof.

In the following descriptions of the drawings, identical or similar elements will be given identical or similar reference numerals. However, it should be noted that the drawings are schematic, and the relationships between thicknesses and planar dimensions, the ratios of thicknesses of layers, and the like are different from the actual ratios, thicknesses, and the like. Therefore, specific thicknesses and dimensions should be determined in light of the following descriptions. Furthermore, it goes without saying that the drawings include elements whose dimensional relationships, ratios, and the like differ from drawing to drawing.

Additionally, the following embodiments illustrate examples of devices, methods, and the like for embodying the technical spirit of the present technique, and the technical spirit of the present technique is not specific to the materials, shapes, structures, arrangements, and the like of the constituent components described hereinafter. The technical spirit of the present technique can be modified in various ways within the technical scope set forth in the claims.

The descriptions will be given in the following order.
1. First Embodiment
2. Second Embodiment
3. Application Example
Example of Application to Electronic Device

### First Embodiment

A first embodiment will describe an example in which the present technique is applied to a light detection device that is a backside-illuminated Complementary Metal Oxide Semiconductor (CMOS) image sensor.

### <<Overall Configuration of Light Detection Device>>

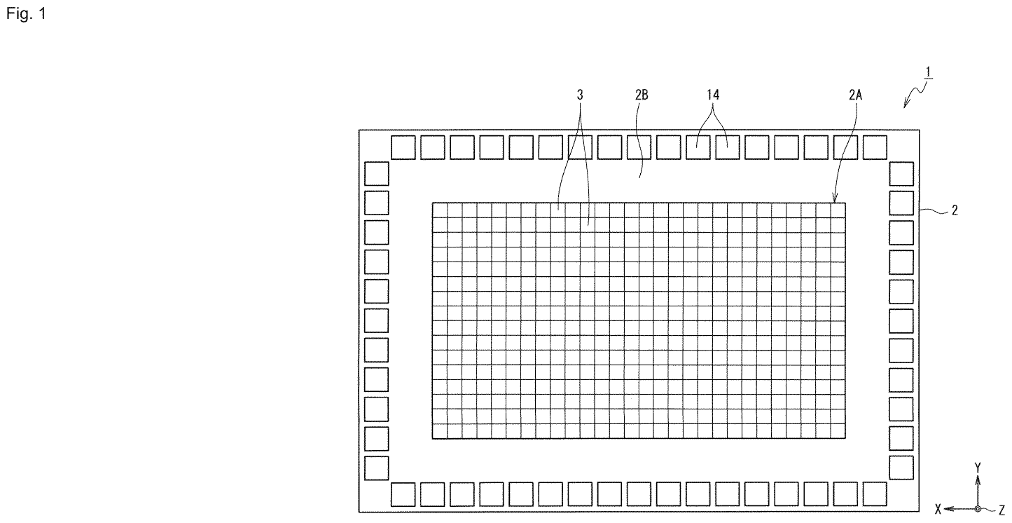

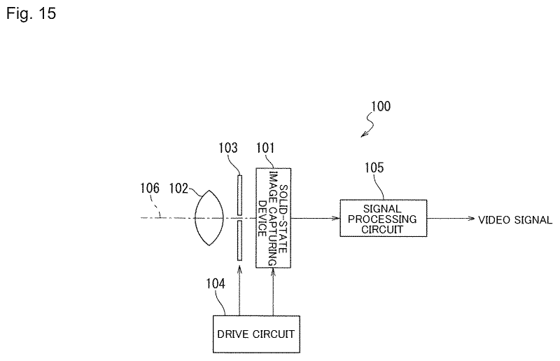

The overall configuration of a light detection device 1 will be described first. As illustrated in FIG. 1, the light detection device 1 according to the first embodiment of the present technique is constituted mainly by a semiconductor chip 2, which has a square two-dimensional planar shape when viewed in plan view. In other words, the light detection device 1 is mounted on the semiconductor chip 2. As illustrated in FIG. 15, the light detection device 1 takes in image light from a subject (incident light 106) through an optical system (an optical lens) 102, converts the amount of incident light 106 formed on an image capturing plane into electrical signals on a pixel-by-pixel basis, and outputs the electrical signals as pixel signals.

As illustrated in FIG. 1, the semiconductor chip 2 on which the light detection device 1 is installed includes a square pixel region 2A provided in a central area and a peripheral region 2B provided outside the pixel region 2A so as to surround the pixel region 2A, in the two-dimensional plane including an X direction and a Y direction intersecting with each other.

The pixel region 2A is a light-receiving surface that receives the light focused by the optical system 102 illustrated in FIG. 15, for example. In the pixel region 2A, a plurality of pixels 3 are arranged in a matrix in the two-dimensional plane including the X direction and the Y direction. In other words, the pixels 3 are arranged in a repeating manner in both the X direction and the Y direction, which intersect with each other in the two-dimensional plane. Note that in the present embodiment, the X direction and the Y direction are orthogonal to each other, for example. A direction orthogonal to both the X direction and the Y direction is a Z direction (a thickness direction, a layering direction). A direction perpendicular to the Z direction is a horizontal direction.

As illustrated in FIG. 1, a plurality of bonding pads 14 are disposed in the peripheral region 2B. Each of the plurality of bonding pads 14, for example, is disposed along one of the four sides of the two-dimensional plane of the semiconductor chip 2. Each of the plurality of bonding pads 14 serves as an input/output terminal used when the semiconductor chip 2 is electrically connected to an external device.

### <Logic Circuitry>

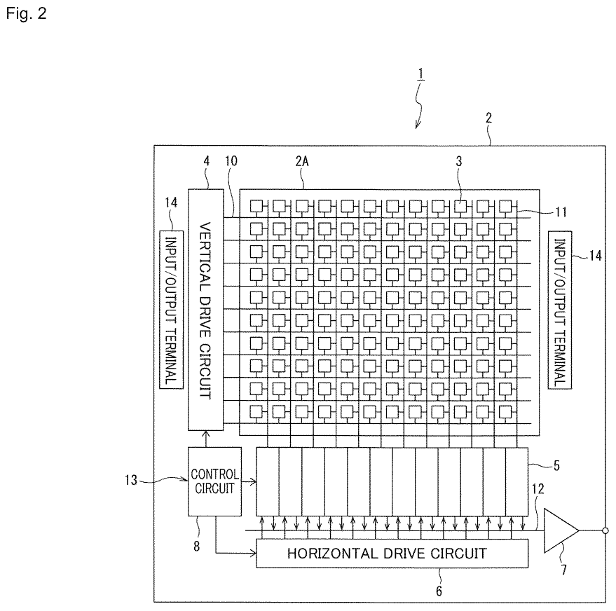

As illustrated in FIG. 2, the semiconductor chip 2 is provided with logic circuitry 13 including a vertical drive circuit 4, column signal processing circuits 5, a horizontal drive circuit 6, an output circuit 7, a control circuit 8, and the like. The logic circuitry 13 is constituted by a Complenentary MOS (CMOS) circuit having an n-channel conductivity type Metal Oxide Semiconductor Field Effect Transistor (MOSFET) and a p-channel conductivity type MOSFET as field effect transistors, for example.

The vertical drive circuit 4 is constituted by a shift register, for example. The vertical drive circuit 4 selects a desired pixel drive line 10 in sequence, supplies a pulse for driving the pixels 3 to the selected pixel drive line 10, and drives respective pixels 3 in units of rows. In other words, the vertical drive circuit 4 sequentially performs selective scanning of the pixels 3 of the pixel region 2A in units of rows in a vertical direction, and supplies pixel signals from the pixels 3, which are based on signal charges generated in accordance with the amount of light received by the photoelectric conversion elements of the pixels 3, to the column signal processing circuits 5 through vertical signal lines 11.

The column signal processing circuits 5 are provided, for example, for corresponding columns of pixels 3, and perform signal processing such as noise removal for each pixel column on a signal output from the pixels 3 corresponding to one row. For example, the column signal processing circuit 5 performs signal processing such as correlated double sampling (CDS) and analog-digital (AD) conversion for removing pixel-specific fixed pattern noise. A horizontal selection switch (not shown) is connected between a horizontal signal line 12 and the output stage of the column signal processing circuit 5.

The horizontal drive circuit 6 is constituted by a shift register, for example. The horizontal drive circuit 6 sequentially selects each column signal processing circuit 5 by sequentially outputting a horizontal scanning pulse to the column signal processing circuit 5, and outputs a pixel signal on which signal processing has been performed from each column signal processing circuit 5 to the horizontal signal line 12.

The output circuit 7 performs signal processing on the pixel signals sequentially supplied from the respective column signal processing circuits 5 through the horizontal signal line 12, and outputs the resulting pixel signals. Examples of the signal processing which may be used include buffering, black level adjustment, column variation correction, various types of digital signal processing, and the like, for example.

The control circuit 8 generates a clock signal or a control signal as a reference for operations of the vertical drive circuit 4, the column signal processing circuit 5, the horizontal drive circuit 6, and the like based on a vertical synchronization signal, a horizontal synchronization signal, and a master clock signal. The control circuit 8 then outputs the generated clock signal or control signal to the vertical drive circuit 4, the column signal processing circuits 5, the horizontal drive circuit 6, and the like.

### <Pixel>

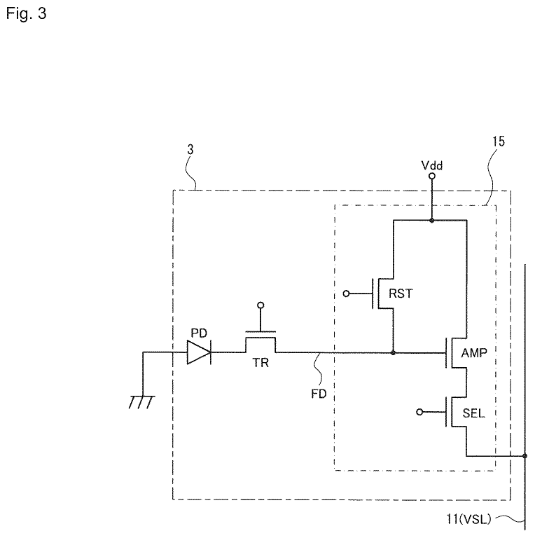

FIG. 3 is an equivalent circuit diagram illustrating an example of the configuration of the pixel 3. The pixel 3 includes a photoelectric conversion element PD, a charge accumulation region (floating diffusion) FD that accumulates (holds) a signal charge obtained from the photoelectric conversion by the photoelectric conversion element PD, and a transfer transistor TR that transfers the signal charge obtained from photoelectric conversion by the photoelectric conversion element PD to the charge accumulation region FD. The pixel 3 also includes a readout circuit 15 electrically connected to the charge accumulation region FD.

The photoelectric conversion element PD generates a signal charge according to the amount of light received. The photoelectric conversion element PD also temporarily accumulates (holds) the generated signal charge. The photoelectric conversion element PD is electrically connected to the source region of the transfer transistor TR on the cathode side, and to a reference potential line (e.g., ground) on the anode side. A photodiode is used as the photoelectric conversion element PD, for example.

The drain region of the transfer transistor TR is electrically connected to the charge accumulation region FD. The gate electrode of the transfer transistor TR is electrically connected to a transfer transistor drive line of the pixel drive line 10 (see FIG. 2).

The charge accumulation region FD temporarily accumulates the signal charge transferred from the photoelectric conversion element PD via the transfer transistor TR.

The readout circuit 15 illustrated reads out the signal charge accumulated in the charge accumulation region FD and outputs a pixel signal based on this signal charge. Although not limited thereto, the readout circuit 15 includes, for example, an amplifying transistor AMP, a selection transistor SEL, and a reset transistor RST as pixel transistors. Each of the transistors (AMP, SEL, and RST) is constituted by a MOSFET having, for example, a gate insulating film formed from a silicon oxide film (SiO₂), a gate electrode, and a pair of main electrode regions functioning as a source region and a drain region. The transistor may be a metal insulator semiconductor FET (MISFET) whose gate insulating film is a silicon nitride film (Si₃N₄) or a layered film including a silicon nitride film, a silicon oxide film, or the like.

The amplifying transistor AMP has a source region electrically connected to a drain region of the selection transistor SEL, and a drain region electrically connected to a power source line Vdd and a drain region of the reset transistor. The gate electrode of the amplifying transistor AMP is electrically connected to the charge accumulation region FD and a source region of the reset transistor RST.

The selection transistor SEL has a source region electrically connected to the vertical signal line 11 (VSL), and a drain electrically connected to a source region of the amplifying transistor AMP. The gate electrode of the selection transistor SEL is electrically connected to a selection transistor drive line of the pixel drive line 10 (see FIG. 2).

The reset transistor RST has a source region electrically connected to the charge accumulation region FD and the gate electrode of the amplifying transistor AMP, and a drain region electrically connected to the power source line Vdd and the drain region of the amplifying transistor AMP. The gate electrode of the reset transistor RST is electrically connected to a reset transistor drive line of the pixel drive line 10 (see FIG. 2).

### <<Specific Configuration of Light Detection Device>>

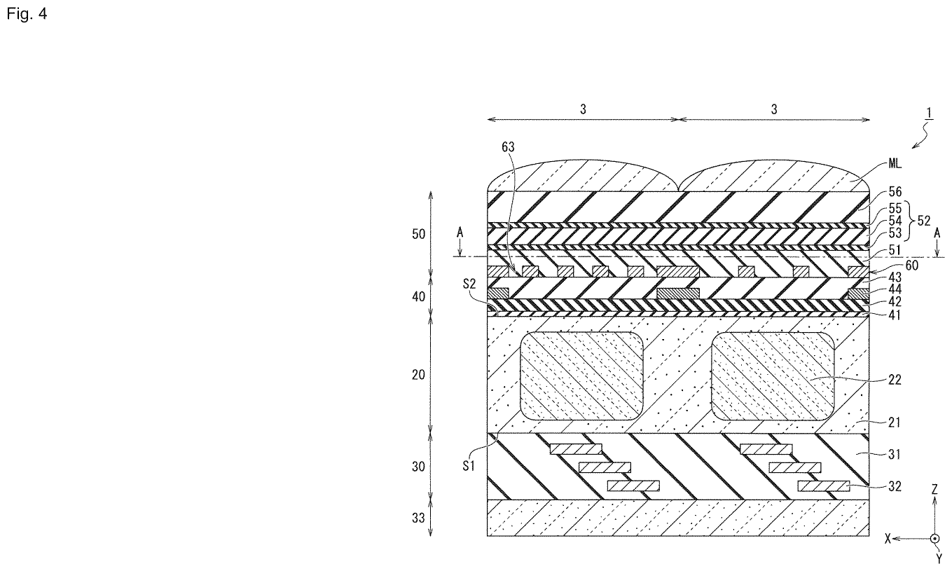

The specific configuration of the light detection device 1 will be described next with reference to FIGS. 4 to 6.

### <Layered Structure of Light Detection Device>

As illustrated in FIG. 4, the light detection device 1 (the semiconductor chip 2) has a layered structure in which a second insulating layer 50, a plasmon filter 60, a first insulating layer 40, a semiconductor layer 20 having a first surface S1 and a second surface S2 located on opposite sides thereof, a wiring layer 30, and a support substrate 33 are layered in that order.

The light detection device 1 (the semiconductor chip 2) includes a microlens (on-chip lens) ML for each pixel 3. The microlens ML is layered, for example, on the side of the second insulating layer 50 opposite from the side on which the first insulating layer 40 is located. The microlens ML is constituted by a resin-based material, for example. Incident light is collected in a photoelectric conversion unit (described later) having passed through the microlens ML. The light detection device 1 also has a light shielding layer 44 provided within the first insulating layer 40. The configuration will be described hereinafter starting with the semiconductor layer 20.

### <Semiconductor Layer>

The semiconductor layer 20 is constituted by a semiconductor substrate. Although not limited thereto, the semiconductor layer 20 is constituted by a single-crystal silicon substrate, for example. The second surface S2 of the semiconductor layer 20 may also be called a “light incidence surface” or a “rear surface”, and the first surface S1 may be called a “device formation surface” or a “main surface”. A part corresponding to the pixel region 2A of the semiconductor layer 20 is provided with a well region 21 of a first conductivity type (e.g., p type) and a semiconductor region 22 of a second conductivity type (e.g., n type) formed in the well region 21 for each pixel 3. The semiconductor region 22 is a photoelectric conversion unit capable of photoelectrically converting incident light. According to this configuration, the photoelectric conversion element PD illustrated in FIG. 3 is configured for each pixel 3. The semiconductor layer 20 includes a plurality of semiconductor regions 22 (photoelectric conversion units) arranged in a two-dimensional array in plan view. The semiconductor regions 22 (photoelectric conversion units) may be isolated from each other by a publicly-known isolation region (not shown). Although not limited thereto, the isolation region is impurity isolation or trench isolation, for example. Although not limited thereto, a part corresponding to the pixel region 2A of the semiconductor layer 20 is constituted by a device such as a transistor or the like constituted by the charge accumulation region FD, the transfer transistor TR, and the readout circuit 15 illustrated in FIG. 3, for each pixel 3. Note that the number of pixels 3 is not limited to that illustrated in FIG. 4.

### <First Insulating Layer>

The first insulating layer 40 is layered on the light incidence surface side of the semiconductor layer 20, and more specifically, on the second surface S2 of the semiconductor layer 20. The first insulating layer 40 is provided so as to cover at least the entire pixel region 2A. Although not limited thereto, the first insulating layer 40 has a layered structure in which, for example, a pinning layer 41, which is an insulating film, an insulating film 42, and an insulating film 43 are layered in this order from the second surface S2 side. The first insulating layer 40 constituted by the insulating films constitutes a first insulating film. More specifically, each of the pinning layer 41, the insulating film 42, and the insulating film 43, which are the insulating films included in the first insulating layer 40, constitutes the first insulating film.

The pinning layer 41 is layered on the second surface S2 of the semiconductor layer 20. The pinning layer 41 is formed from a high dielectric material having a negative fixed charge through a publicly-known method. The negative fixed charge of the pinning layer 41 adds an electric field to the interface with the semiconductor layer 20, and thus a positive charge accumulation region is formed at the part of the interface with the semiconductor layer 20. This makes it possible to suppress an increase in dark current. Although not limited thereto, hafnium oxide (HfO₂), zirconium oxide (ZrO₂), tantalum oxide (Ta₂O₅), and the like can be given as examples of the material constituting the pinning layer 41. The pinning layer 41 can also function as an anti-reflection film.

The insulating film 42 is layered on the surface of the pinning layer 41 on the side opposite from the side on which the semiconductor layer 20 is located. The insulating film 43 is provided so as to cover the light shielding layer 44 layered on the surface of the insulating film 42 on the side opposite from the side on which the pinning layer 41 is located. Although not limited thereto, the surface of the insulating film 43 on the second insulating layer 50 side is flattened using a publicly-known method such as chemical mechanical polishing (CMP), for example. Although not limited thereto, silicon oxide (SiO₂), silicon oxynitride (SiON), and aluminum oxide (Al₂O₃) can be given as examples of the material constituting the insulating films 42 and 43. The present embodiment will describe the insulating films 42 and 43 as being constituted by silicon oxide.

### <Light Shielding Layer>

The light shielding layer 44 is provided so as to cover the surface of the insulating film 42 on the side opposite from the side on which the pinning layer 41 is located. It is desirable that the light shielding layer 44 be provided in a region overlapping the boundary (isolation region) between the pixels in plan view, and be composed of a material that does not easily transmit light. Tungsten (W), aluminum (Al), copper (Cu), and the like can be given as examples of the material constituting the light shielding layer 44. The present embodiment will describe the light shielding layer 44 as being constituted by tungsten.

### <Second Insulating Layer>

The second insulating layer 50 is provided so as to cover at least the entire pixel region 2A. Although not limited thereto, the second insulating layer 50 has a layered structure in which, for example, an insulating film 51, an insulating film 52, and a flattening film 56, which is an insulating film, are layered in that order. The insulating film 51 constitutes a second insulating film, and the insulating film 52 constitutes a third insulating film.

The insulating film 51 is layered on the plasmon filter 60. More specifically, the plasmon filter 60 is covered so as to fill openings 63 (described later). The surface of the insulating film 51 on the insulating film 52 side is flattened by, for example, adjusting the thickness or the formation method of the insulating film 51. Alternatively, the surface of the insulating film 51 on the insulating film 52 side may be flattened through CMP. Although not limited thereto, silicon oxide (SiO₂), silicon oxynitride (SiON), and aluminum oxide (Al₂O₃) can be given as examples of the material constituting the insulating film 51. It is desirable that the material constituting the insulating film 51 be selected according to the type of optical elements such as the plasmon filter 60. The present embodiment will describe the insulating film 51 as being constituted by silicon oxide.

The insulating film 52 functions as a passivation film, for example. Although not limited thereto, the insulating film 52 functions, for example, as a protective film that suppresses the entry of moisture and the like, which suppresses corrosion. The insulating film 52 can also function as an anti-reflection film, for example. The insulating film 52 has a layered structure in which a film 53, a film 54, and a film 55 are layered in that order from the insulating film 51 side. The insulating film 52, and the film 53 to the film 55, each constitutes the third insulating film. Although the present embodiment describes an example in which the insulating film 52 has a three-layer layered structure, the layered structure is not limited to the three layers. The insulating film 52 may have a layered structure including two layers, or four or more layers. Additionally, the insulating film 52 may have only one layer of film.

Although not limited thereto, silicon nitride (Si₃N₄), silicon oxynitride (SiON), and aluminum oxide (Al₂O₃) can be given as examples of the material constituting the insulating film 52. The film 53, the film 54, and the film 55 may be constituted by different materials from each other, or may be constituted by the same material. The present embodiment will describe the film 53 and the film 55 as being constituted by a silicon oxynitride film, and the film 54 as being constituted by silicon nitride. The film 53 and the film 55 function as anti-reflection films. The refractive index of the film 53 has a value between the refractive index of the film 54 and the refractive index of the insulating film 51, and the refractive index of the film 55 has a value between the refractive index of the film 54 and the refractive index of the insulating film 56.

The flattening film 56 is provided for flattening the surface on which the microlens ML is formed. The flattening film 56 is constituted by a publicly-known insulating film. Although not limited thereto, publicly-known resin materials such as silicon oxide, acrylic resin, and the like can be given as examples of the material constituting the flattening film 56.

### <Plasmon Filter>

The plasmon filter 60 is an optical element. The light detection device 1 includes the plasmon filter 60 layered on the surface of the insulating film 43 opposite from the side on which the semiconductor layer 20 is located. More specifically, one surface of the plasmon filter 60 is in contact with the surface of the insulating film 43 opposite from the side on which the semiconductor layer 20 is located, and the other surface is in contact with the insulating film 51. The plasmon filter 60 is a color filter that utilizes surface plasmon resonance. The plasmon filter 60 functions as a color filter which creates a structure by forming a periodic hole array having an optical wavelength of about half that of a metal thin film, and further covering the metal thin film with an oxide film, to excite and propagate surface plasmons having a specific frequency component determined by the period of the hole array at the interface between the metal and the oxide film. In other words, the plasmon filter 60 is an optical element that can select specific light and supply the selected light to the photoelectric conversion unit (semiconductor region 22). The plasmon filter 60 can select different wavelengths of light according to the type of hole array, and can function as a multispectral filter.

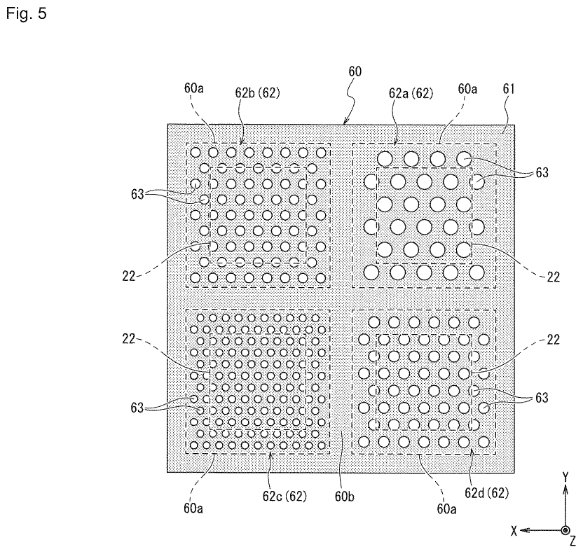

As illustrated in FIG. 5, the plasmon filter 60 has a base material 61 and a plurality of openings 63 provided in the base material 61. The base material 61 is a metal film layered on the insulating film 43. Each of the openings 63 is a circular hole when viewed in plan view, and penetrates the base material 61 in the thickness direction. In the present embodiment, the array of the plurality of openings 63 (the hole array) is called an “opening array 62”. FIG. 5 illustrates four types of opening arrays 62a, 62b, 62c, and 62d. Note that the types of the opening array in the plasmon filter 60 is not limited to four types. The opening arrays 62a, 62b, 62c, and 62d have openings 63 which have different diameters in plan view, and the pitches at which the openings 63 are provided are also different. Changing the diameter and pitch of the openings 63 makes it possible to change the wavelength of the light to be selected. Multispectral filters can be configured by arranging different types of opening arrays. The size and pitch of the openings 63 tend to be larger in an opening array 62 that selects long-wavelength light than an opening array 62 that selects short-wavelength light. Note that the opening arrays 62a, 62b, 62c, and 62d are simply called “opening arrays 62” when not being distinguished from one another. Of the base material 61 that constitutes the plasmon filter 60, the region in which the opening array 62 is provided is called an “opening region 60a”, and the region between opening regions 60a is called a “frame region 60b”. The opening region 60a is provided in a position overlapping the photoelectric conversion unit (semiconductor region 22) in plan view. The frame region 60b is provided in a position overlapping the light shielding layer 44 and the boundary (isolation region) between pixels in plan view.

Although not limited thereto, gold (Au), aluminum (Al), an alloy containing gold or aluminum, tungsten (W), and the like can be given as examples of the material constituting the base material 61 of the plasmon filter 60. It is desirable that the material constituting the base material 61 of the plasmon filter 60 be selected according to the type of the optical element. The present embodiment will describe the base material 61 as being constituted by aluminum.

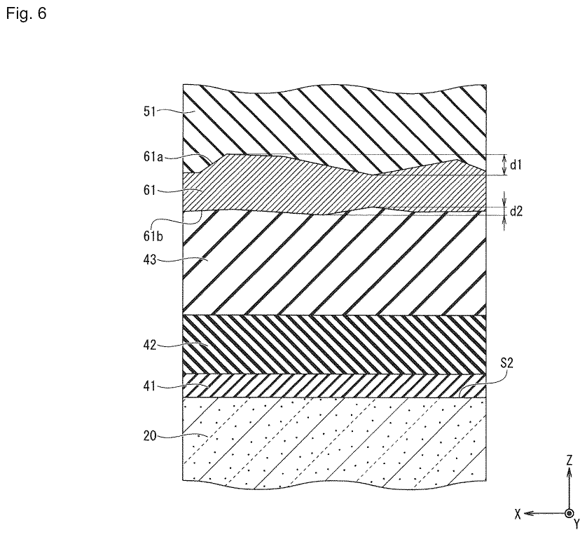

FIG. 6 is a partial enlarged view illustrating the longitudinal cross-sectional structure of the base material 61. Note that the cross-section in FIG. 6 is a cross-section of a part of the base material 61 where the openings 63 are not provided. Of the surfaces of the base material 61, the surface on the insulating film 51 side is called a “surface 61a”, and the surface on the insulating film 43 side is called a “surface 61b”. A surface 51a (61a) has unevenness (surface roughness) provided across the entire surface. That is, the unevenness (surface roughness) of the surface 51a (61a) is the same in different pixels 3. Note that the magnitude of the unevenness of the surface 61a is defined by a distance d1 indicated in the figure. The distance d1 indicates a range of heights (height range) along the Z direction of the unevenness in the surface 61a. The magnitude of the unevenness of the surface 61a, i.e., the distance d1, is set to at least 5 nm and at most 100 nm. By providing unevenness in the surface 61a, when light incident on the light detection device 1 hits the surface 61a of the base material 61, the light is at least partially scattered and reflected by the unevenness of the surface 61a. This makes it possible to suppress interference caused by reflected light in the second insulating layer 50.

In addition, the unevenness (surface roughness) of the surface 61a of the base material 61 (metal film) is greater than the unevenness of the surface 61b of the base material 61. The magnitude of the unevenness of the surface 61b is defined by a distance d2 indicated in the figure. The distance d2 indicates a range of heights (height range) along the Z direction of the unevenness in the surface 61b. The distance d1 is set to be greater than the distance d2 (d1>d2). In other words, the distance d2 is set to be smaller than the distance d1. There are situations where the light transmitted through the plasmon filter 60 is reflected by the pinning layer 41, the semiconductor layer 20, and the like, returns to the plasmon filter 60, and hits the surface 61b. Even in such a case, the unevenness of the surface 61b is smaller than the unevenness of the surface 61a, which makes it possible to suppress extensive scattered reflection of light by the surface 61b. This makes it possible to suppress situations where light reflected by the surface 61b mixes with colors from adjacent pixels. Furthermore, the height range of the unevenness in the surface 61a is set to be greater than the height range of the unevenness (surface roughness) in the surface of the film provided between the plasmon filter 60 and the semiconductor layer 20. For example, the height range of the unevenness in the surface 61a is greater than the height range of the unevenness (surface roughness) in the surface of the pinning layer 41 on the semiconductor layer 20 side and the height range of the unevenness (surface roughness) in the surface of the insulating film 42 on the pinning layer 41 side (the semiconductor layer 20 side). It should be noted that the two surfaces of different films in contact with each other or the two surfaces of the film and the semiconductor layer 20 are generally considered to have about the same degree of unevenness (surface roughness).

### <<Method for Manufacturing Light Detection Device>>

A method for manufacturing the light detection device 1 will be described hereinafter. More specifically, a method for manufacturing the plasmon filter 60 will be described. For the other parts, publicly-known methods may be used, and descriptions thereof will therefore be omitted. First, a substrate having the support substrate 33 to the insulating film 43 is prepared using a publicly-known method. The exposed surface of the insulating film 43 is flattened using a publicly-known method such as chemical mechanical polishing (CMP), for example. Then, a metal film constituting the base material 61 of the plasmon filter 60 is layered on the exposed surface of the insulating film 43. Thereafter, heat treatment is performed to increase the unevenness of the surface 61a of the base material 61. The composition of the metal film constituting the base material 61 (e.g., the types of additives and the amounts thereof), the film formation temperature, and the heat treatment conditions are set as appropriate to control the magnitude of the unevenness of the surface 61a. The desired unevenness may be formed in the surface 61a by performing dry etching, wet etching, or the like after forming the base material 61. Next, the openings 63 are formed in the base material 61 using a publicly-known lithography technique and an etching technique, and the base material 61 provided with the openings 63 is covered with the insulating film 51. This substantially completes the plasmon filter 60.

### <<Main Effects of First Embodiment>>

The main effects of the first embodiment will be described hereinafter, but a past example will be described first. The base material of the plasmon filter is constituted by a metal, and therefore as a high reflectance and tends to reflect light. Light reflected by the microlens-side surface of the plasmon filter may produce interference at the insulating film provided between the plasmon filter and the microlens. When such light interference occurs, large ripples may arise in the spectral properties of the plasmon filter, making it difficult to achieve the spectral properties intended by design.

In addition, the light reflected by the microlens-side surface of the plasmon filter may be reflected again upon hitting glass provided as part of a package outside the light detection device. Flare may arise when light reflected by glass re-enters the light detection device.

In contrast, the light detection device 1 according to the first embodiment of the present technique is provided with unevenness in the surface 61a of the base material 61 of the plasmon filter 60. Accordingly, when light incident on the light detection device 1 hits the surface 61a of the base material 61, the light is at least partially scattered and reflected by the unevenness of the surface 61a. Since the scattered reflected light travels at an oblique angle, that light is unlikely to interfere with the incident light. It is therefore possible to suppress interference caused by reflected light in the second insulating layer 50. This makes it possible to suppress large ripples in the spectral properties of the plasmon filter 60.

In addition, because the light detection device 1 according to the first embodiment of the present technique suppresses interference by providing unevenness in the surface 61a of the base material 61, which makes it possible to suppress flare.

In addition, in the light detection device 1 according to the first embodiment of the present technique, the unevenness in the surface 61b of the plasmon filter 60 is smaller than the unevenness in the surface 61a, which makes it possible to suppress extensive scattered reflection of light by the surface 61b. As a result, even if the light transmitted through the plasmon filter 60 is reflected by the pinning layer 41, the semiconductor layer 20, or the like and returns to the plasmon filter 60, the scattered reflection of the light by the surface 61b can be suppressed, which makes it possible to suppress situations where light reflected by the surface 61b mixes with colors from adjacent pixels.

### <<Variation on First Embodiment>>

A variation on the first embodiment will be described hereinafter.

### <Variation 1>

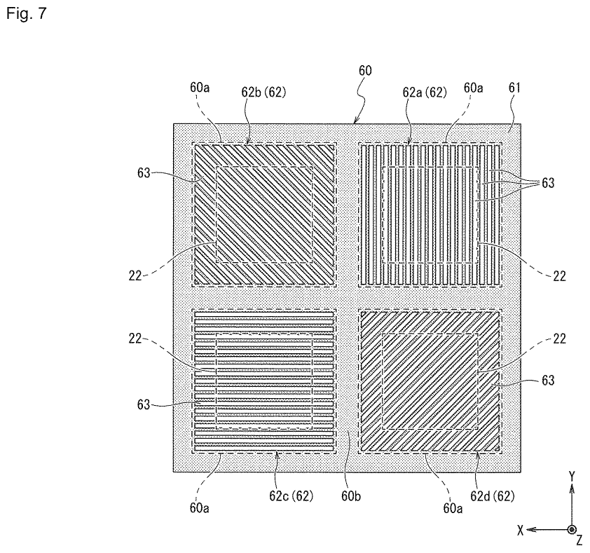

Although the light detection device 1 according to the first embodiment was provided with the plasmon filter 60 as an optical element, the present technique is not limited thereto. The light detection device 1 according to Variation 1 on the first embodiment may be provided with the wire grid polarizer 60, illustrated in FIG. 7, as an optical element.

The wire grid polarizer 60 includes the base material 61 and an opening array 62 formed in the base material 61, and is an optical element that selects specific light and supplies the selected light to the semiconductor region 22 (the photoelectric conversion unit). More specifically, the wire grid polarizer 60 is an optical element that selects light having a specific polarization plane according to the direction in which the openings 63 are arranged in the opening array 62, and supplies the selected light to the semiconductor region 22 (the photoelectric conversion unit). The openings 63 are linear in plan view and are arranged parallel to a shorter direction. The pitch at which the openings 63 are arranged is set to be significantly smaller than the effective wavelength of incoming electromagnetic waves. The openings 63 penetrate the base material 61 in the thickness direction. Of the incident light, the wire grid polarizer 60 reflects polarized light parallel to the longer direction of the openings 63 (extinction axis light), and transmits polarized light perpendicular to the longer direction of the openings 63 (transmission axis light).

The wire grid polarizer 60 has a plurality of types of opening arrays 62 with in which the openings 63 are arranged in different directions. It is desirable that the base material 61 be configured using a metal material having a reflectance to suppress polarization loss. FIG. 7 illustrates an example in which the wire grid polarizer 60 has four types of opening arrays 62 (opening arrays 62a, 62b, 62c, and 62d), for example. The direction in which the openings 63 of the opening array 62a are arranged is a direction parallel to the X direction. The direction in which the openings 63 of the opening array 62b are arranged is a direction at a 45-degree angle to the X direction. The direction in which the openings 63 of the opening array 62c are arranged is a direction at a 90-degree angle to the X direction. The direction in which the openings 63 of the opening array 62d are arranged is a direction at a 135-degree angle to the X direction.

It should be noted that in the wire grid polarizer 60, the unevenness characteristics of the surfaces 61a and 61b of the base material 61 are the same as when the plasmon filter 60 is used, and will therefore not be described here.

The light detection device 1 according to Variation 1 on the first embodiment provides effects similar to those of the light detection device 1 according to the first embodiment described above.

### Second Embodiment

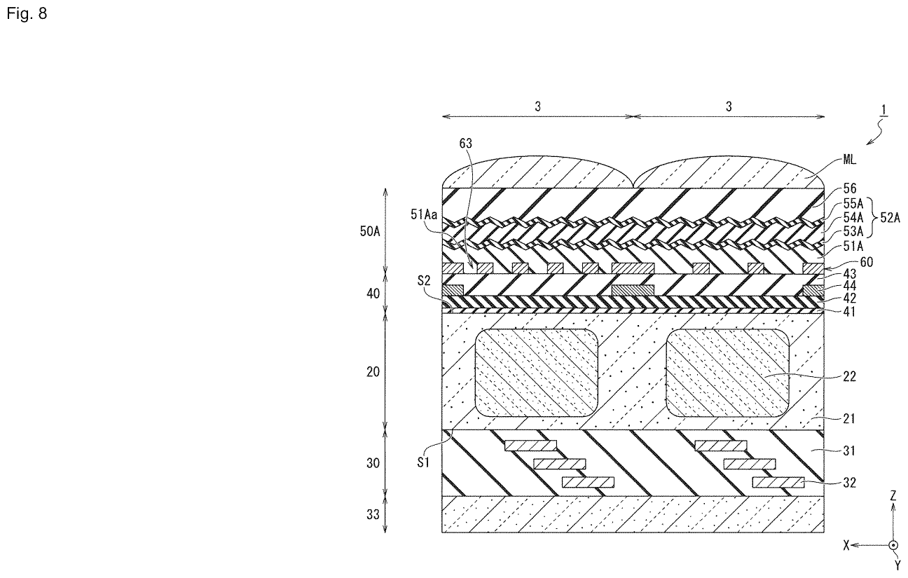

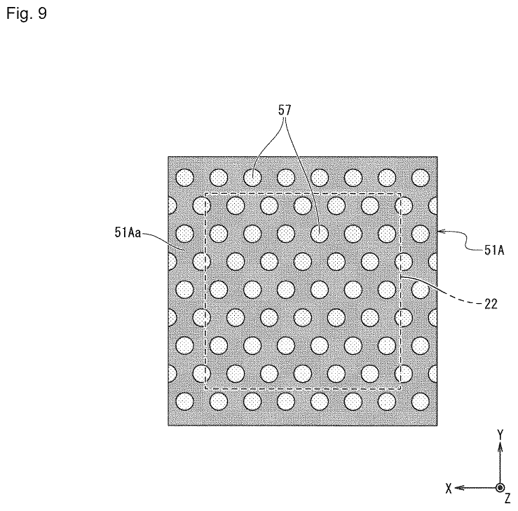

A second embodiment of the present technique, illustrated in FIGS. 8 and 9, will be described hereinafter. The light detection device 1 according to the present second embodiment differs from the light detection device 1 according to the first embodiment described above in that a second insulating layer 50A is provided instead of the second insulating layer 50. Aside from this, the configuration of the light detection device 1 is basically the same as that of the light detection device 1 according to the first embodiment described above. Note that the constituent elements already described will be given the same reference signs, and descriptions thereof will be omitted. In addition, the definition of the height range of the unevenness is the same as in the first embodiment.

### <<Configuration of Light Detection Device>>

### <Second Insulating Layer>

As illustrated in FIG. 8, although not limited thereto, the second insulating layer 50A has a layered structure in which, for example, an insulating film 51A, an insulating film 52A, and the flattening film 56, which is an insulating film, are layered in that order. The insulating film 51A constitutes the second insulating film, and the insulating film 52A constitutes the third insulating film. Although the insulating film 51A and the insulating film 52A have shapes different from those of the insulating film 51 and the insulating film 52, the rest of the configurations thereof are the same as in the first embodiment described above.

The surface of the insulating film 51A on the insulating film 52A side thereof is called a “surface 51Aa”. The surface 51Aa has unevenness provided across a plurality of the pixels 3. More specifically, the surface 51Aa has unevenness provided in the same manner across a plurality of the pixels 3. In other words, the unevenness (surface roughness) of the surface 51Aa is the same in different pixels 3. The height range of the unevenness of the surface 51Aa is set to at least 5 nm and at most 100 nm. In addition, the unevenness (surface roughness) of the surface 51Aa is greater than the unevenness of the surface 61b, which is the surface of the base material 61 on the insulating film 43 side thereof. More specifically, the height range of the unevenness in the surface 51Aa is set to be greater than the height range of the unevenness in the surface 61b. The unevenness is set, for example, to about the same magnitude as the wavelength selected by the plasmon filter 60.

Additionally, the height range of the unevenness in the surface 51Aa is greater than the height range of the unevenness (surface roughness) in the surface of the film provided between the plasmon filter 60 and the semiconductor layer 20. For example, the height range of the unevenness in the surface 51Aa is greater than the height range of the unevenness (surface roughness) in the surface of the pinning layer 41 on the semiconductor layer 20 side and the height range of the unevenness (surface roughness) in the surface of the insulating film 42 on the pinning layer 41 side (the semiconductor layer 20 side).

As illustrated in FIG. 9, the unevenness of the surface 51Aa is constituted by a plurality of holes 57 provided in the surface 51Aa. Although the holes 57 are circular in plan view in the example illustrated in FIG. 9, the shape is not limited thereto, and other shapes such as a square, for example, may be used instead. Additionally, the holes 57 are arranged with regularity, but may instead be arranged randomly. The depth of the holes 57 in the thickness direction of the insulating film 51A is about the same as the height range of the unevenness in the surface 51Aa. By providing unevenness in the surface 51Aa, when light incident on the light detection device 1 hits the surface 51Aa of the insulating film 51A, the light is at least partially scattered and reflected by the unevenness of the surface 51Aa. This makes it possible to suppress interference caused by reflected light in the second insulating layer 50A.

The insulating film 52A illustrated in FIG. 8 functions as a passivation film, for example. The insulating film 52A has a layered structure in which a film 53A, a film 54A, and a film 55A are layered in that order from the insulating film 51A side. The insulating film 52A, and the film 53A to the film 55A, each constitutes the third insulating film. Although the present embodiment describes an example in which the insulating film 52A has a three-layer layered structure, the layered structure is not limited to the three layers. The insulating film 52A may have a layered structure including two layers, or four or more layers. Additionally, the insulating film 52A may have only one layer of film.

The insulating film 52A is layered on the surface 51Aa of the insulating film 51A. More specifically, the film 53A of the insulating film 52A is layered on the surface 51Aa of the insulating film 51A. The insulating film 51A functions as a base material for the film 53A. The magnitude of the unevenness of the surface of the film 53A on the semiconductor layer 20 side thereof is determined by the unevenness of the base material of the film 53A (the surface 51Aa of the insulating film 51A). The magnitude of the unevenness of the surface of the film 53A on the side opposite from the side on which the base material is located (the microlens ML side) is controlled by the unevenness of the base material and the film forming conditions and film thickness of the film 53A. The film 53A functions as a base material for the film 54A, and the film 54A functions as a base material for the film 55A. In the present embodiment, the film 53A, the film 54A, and the film 55A are layered under conditions which ensure that the surface on the side opposite from the side on which the base material is located is not greatly flattened relative to the unevenness of the base material. As such, the insulating film 52A, and the film 53A to the film 55A, have unevenness that corresponds to the unevenness of the surface 51Aa, on both sides in the thickness direction. By providing unevenness in the surface of the insulating film 52A, when light incident on the light detection device 1 hits the surface of the insulating film 52A, the light is at least partially scattered and reflected by the unevenness of the surface of the insulating film 52A. This makes it possible to suppress interference caused by reflected light in the second insulating layer 50.

### <<Method for Manufacturing Light Detection Device>>

A method for manufacturing the light detection device 1 will be described hereinafter. More specifically, a method for manufacturing the surface 51Aa and the insulating film 52A will mainly be described. For the other parts, publicly-known methods may be used, and descriptions thereof will therefore be omitted. First, the insulating film 51A covering the plasmon filter 60 is provided. Thereafter, a plurality of the holes 57 are formed in the exposed surface of the insulating film 51A using a publicly-known lithography technique and etching technique. It should be noted that the holes 57 are provided in a region of the surface 51Aa that at least overlaps with the pixel region 2A in plan view. The holes 57 are provided in the same manner for all the pixels 3. The film 53A, the film 54A, and the film 55A are then layered in that order. The film 53A, the film 54A, and the film 55A are layered under conditions which ensure that the surface on the side opposite from the side on which the base material is located is not greatly flattened relative to the unevenness of the base material.

### <<Main Effects of Second Embodiment>>

The main effects of the second embodiment will be described hereinafter. The light detection device 1 according to the second embodiment provides effects similar to those of the light detection device 1 according to the first embodiment described above.

In the light detection device 1 according to the second embodiment of the present technique, in addition to the surface 61a of the plasmon filter 60, the surface 51Aa of the insulating film 51A and the surface of the insulating film 52A are also provided with unevenness, and thus the surface that scatters and reflects light can be increased along the Z direction. Accordingly, the chances for scattered reflection of the light incident on the light detection device 1 are increased on the microlens ML side from the surface 61a of the plasmon filter 60, which makes it possible to further suppress light interference.

Additionally, in the light detection device 1 according to the second embodiment of the present technique, the unevenness provided in the surface 51Aa of the insulating film 51A and the surface of the insulating film 52A has a small effect, if any, on the optical properties of the plasmon filter 60, for example.

It should be noted that in the light detection device 1 according to the second embodiment, both the surface 61a of the base material 61 and the surface 51Aa of the insulating film 51A have unevenness that is greater than the unevenness of the surface 61b of the base material 61 and the unevenness of the surface of the film provided between the plasmon filter 60 and the semiconductor layer 20, but the present technique is not limited thereto. Of the surface 61a and the surface 51Aa, only the surface 51Aa may have unevenness that is greater than the unevenness of the surface 61b of the base material 61 and the unevenness of the surface of the film provided between the plasmon filter 60 and the semiconductor layer 20.

Additionally, the insulating film 51A is constituted by a single layer of film in the example illustrated in FIG. 8, but the insulating film 51A may have a layered structure in which a plurality of layers of film are layered.

### <<Variation on Second Embodiment>>

Variations on the second embodiment will be described hereinafter.

### <Variation 1>

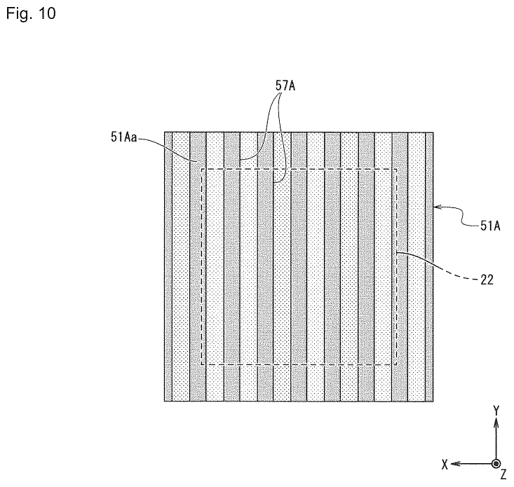

In the light detection device 1 according to the second embodiment, the unevenness of the surface 51Aa was formed by a plurality of holes 57 provided in the surface 51Aa, but the present technique is not limited thereto. As illustrated in FIG. 10, in the light detection device 1 according to Variation 1 on the second embodiment, the unevenness of the surface 51Aa may be formed by a plurality of grooves 57A provided in the surface 51Aa. The depth of the grooves 57A in the thickness direction of the insulating film 51A is about the same as the height range of the unevenness in the surface 51Aa.

The light detection device 1 according to Variation 1 on the second embodiment provides effects similar to those of the light detection device 1 according to the second embodiment described above.

### <Variation 2>

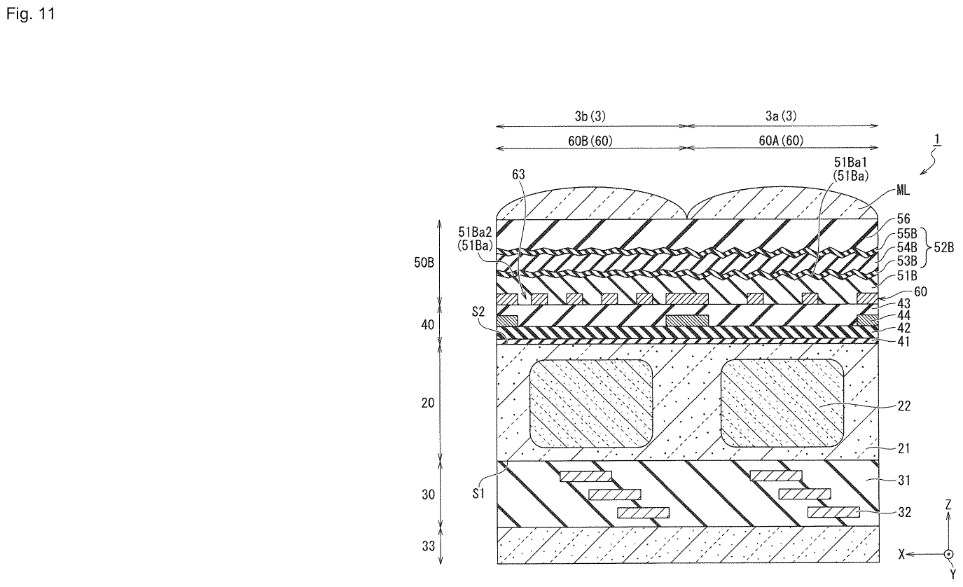

In the light detection device 1 according to the second embodiment, unevenness was provided in the surface 51Aa in the same manner across the plurality of pixels 3, but the present technique is not limited thereto. As illustrated in FIG. 11, in the light detection device 1 according to Variation 2 on the second embodiment, the magnitude of the unevenness may be changed between the plasmon filters 60 which select different wavelengths.

The light detection device 1 according to Variation 2 on the second embodiment has a second insulating layer 50B instead of the second insulating layer 50A. The other configurations of the light detection device 1 are basically the same as in the light detection device 1 of the second embodiment described above. Although not limited thereto, the second insulating layer 50B has a layered structure in which, for example, an insulating film 51B, an insulating film 52B, and the flattening film 56, which is an insulating film, are layered in that order. The insulating film 51B constitutes the second insulating film, and the insulating film 52B constitutes the third insulating film.

Of the plasmon filters 60, the example in FIG. 11 illustrates a plasmon filter 60A in the part that overlaps with a pixel 3a in plan view and a plasmon filter 60B in the part that overlaps with a pixel 3b in plan view. The wavelengths of the light selected are different between the plasmon filter 60A and the plasmon filter 60B.

More specifically, the plasmon filter 60B (a first optical element) selects light of a first wavelength, and the plasmon filter 60A (a second optical element) selects light of a second wavelength longer than the first wavelength. The size and pitch of the openings 63 in the plasmon filters 60 tend to be larger in an opening array 62 that selects long-wavelength light than an opening array 62 that selects short-wavelength light. Although not limited thereto, for example, the plasmon filter 60A has the opening array 62a illustrated in FIG. 5, and the plasmon filter 60B has an opening array 62b in which the openings 63 are smaller in size and pitch than the opening array 62a. With such a configuration, the photoelectric conversion unit of the pixel 3a which overlaps with the plasmon filter 60A in plan view detects the second wavelength, and the photoelectric conversion unit of the pixel 3b which overlaps with the plasmon filter 60B in plan view detects the first wavelength. The first wavelength is, for example, light such as blue or green, and the second wavelength is, for example, light such as red or infrared. It goes without saying that the plasmon filter 60 has other parts that select wavelengths aside from the first wavelength and the second wavelength.

The surface of the insulating film 51B on the insulating film 52B side thereof is called a “surface 51Ba”. Of the surface 51Ba, a region that overlaps with the plasmon filter 60A in plan view is called a “surface 51Ba1”, and a region that overlaps with the plasmon filter 60B in plan view is called a “surface 51Ba2”. Here, long-wavelength light is more likely to produce light interference than short-wavelength light. As such, the plasmon filter 60A that selects the second wavelength is more susceptible to ripples in the spectral properties and flare than the plasmon filter 60A that selects the first wavelength. Accordingly, in the present variation, the unevenness of the surface 51Ba that overlaps with the plasmon filter 60A that selects the light of the second wavelength in plan view is greater than the unevenness of a surface 51Bb that overlaps with the plasmon filter 60B that selects the light of the first wavelength in plan view. More specifically, the height range of the unevenness (surface roughness) in the surface 51Ba1 is set to be greater than the height range of the unevenness (surface roughness) in the surface 51Ba2. Through this, the surface 51Ba that overlaps with the plasmon filter 60A that selects the light of the second wavelength in plan view scatters and reflects incident light more than the surface 51Bb that overlaps with the plasmon filter 60B that selects the light of the first wavelength in plan view.

It should be noted that the relationship between (i) the height range of the unevenness in the surface 51Ba and the height range of the unevenness in the surface 51Bb and (ii) the height range of the unevenness (surface roughness) in the surface of the film provided between the plasmon filter 60 and the semiconductor layer 20 is the same as in the second embodiment described above. In addition, the unevenness of the surface 51Ba is provided regardless of the positions of the openings 63 in the plasmon filter 60 in plan view.

The insulating film 52B functions as a passivation film, for example. The insulating film 52B has a layered structure in which a film 53B, a film 54B, and a film 55B are layered in that order from the insulating film 51B side. The insulating film 52B, and the film 53B to the film 55B, each constitutes the third insulating film. Although the present embodiment describes an example in which the insulating film 52B has a three-layer layered structure, the layered structure is not limited to the three layers. The insulating film 52B may have a layered structure including two layers, or four or more layers. Additionally, the insulating film 52B may have only one layer of film.

The insulating film 52B is layered on the surface 51Ba of the insulating film 51B. As such, each of the film 53B to the film 55B has unevenness that corresponds to the unevenness of the surface 51Ba, on both sides in the thickness direction. To be more specific, in each of the film 53B to the film 55B, both surfaces, in the thickness direction, of the parts layered on the surface 51Ba1 have unevenness that corresponds to the unevenness of the surface 51Ba1, and both surfaces, in the thickness direction, of the parts layered on the surface 51Ba2 have unevenness that corresponds to the unevenness of the surface 51Ba2. The unevenness on both sides in the thickness direction of each of the film 53B to the film 55B is greater in the parts layered on the surface 51Ba1 than the parts layered on the surface 51Ba2. In this manner, of the insulating film 52B, the unevenness of the part that overlaps with the plasmon filter 60A that selects the light of the second wavelength in plan view is greater than the unevenness of the part that overlaps with the plasmon filter 60B that selects the light of the first wavelength in plan view. Through this, of the surfaces of the insulating film 52B, the surface that overlaps with the plasmon filter 60A that selects the light of the second wavelength in plan view scatters and reflects incident light more than the surface that overlaps with the plasmon filter 60B that selects the light of the first wavelength in plan view.

A method for manufacturing the light detection device 1 will be described hereinafter. More specifically, a method for manufacturing the surface 51Ba will mainly be described. For the other parts, publicly-known methods may be used, and descriptions thereof will therefore be omitted. First, the insulating film 51B covering the plasmon filter 60 is provided. Then, the plurality of the holes 57 are formed in sequence in each of the surface 51Ba1 of the insulating film 51B and the surface 51Ba2 of the insulating film 51B, using a publicly-known lithography technique and etching technique. Although not limited thereto, for example, first, a plurality of the holes 57 are formed in the surface 51Ba1 of the insulating film 51B, and then a plurality of the holes 57 are formed in the surface 51Ba2 of the insulating film 51B. In this manner, the lithography technique and the etching technique are repeated for each size and pitch of the holes 57 to be formed. The film 53B, the film 54B, and the film 55B are then layered in that order. The film 53B, the film 54B, and the film 55B are layered under conditions which ensure that the surface on the side opposite from the side on which the base material is located is not greatly flattened relative to the unevenness of the base material.

The light detection device 1 according to Variation 2 on the second embodiment provides effects similar to those of the light detection device 1 according to the second embodiment described above.

In the light detection device 1 according to Variation 2 on the second embodiment, of the surface 51Ba of the insulating film 51B, the unevenness of the region that, in plan view, overlaps with the plasmon filter 60A that selects the second wavelength that is longer than the first wavelength (the surface 51Ba1) is greater than the unevenness of the region that, in plan view, overlaps with the plasmon filter 60B that selects the first wavelength (the surface 51Ba2). As such, interference caused by reflected light can be suppressed more in the plasmon filter 60A that selects the long wavelength (the first wavelength), at which ripples in the spectral properties and flare are more likely to arise.

In the light detection device 1 according to Variation 2 on the second embodiment, of the surface 51Ba on the side on the insulating film 51B, the unevenness of the region that, in plan view, overlaps with the plasmon filter 60B that selects the first wavelength that is shorter than the second wavelength (the surface 51Ba2) is smaller than the unevenness of the region that, in plan view, overlaps with the plasmon filter 60A that selects the second wavelength (the surface 51Ba1). As such, in the plasmon filter 60B, which selects short-wavelength light in which ripples in the spectral properties and flare are less likely to arise than in long-wavelength light, setting the unevenness to an appropriate magnitude makes it possible to suppress situations where scattered reflection increases more than necessary, which in turn makes it possible to prioritize focusing characteristics.

In Variation 2 on the second embodiment, of the surface 51Ba, the unevenness of the region that, in plan view, overlaps with the plasmon filter 60B that selects the first wavelength that is shorter than the second wavelength is set to be smaller than the unevenness of the region that, in plan view, overlaps with the plasmon filter 60A that selects the second wavelength. However, it should be noted that the technique is not limited thereto. Of the surface 51Ba, unevenness need not be provided in the region that, in plan view, overlaps with the plasmon filter 60B that selects the first wavelength, at which the influence on interference is limited to some extent. This makes it possible to prioritize the focusing characteristics more.

It goes without saying that the surface 51Ba of the insulating film 51B may have other regions aside from the surface 51Ba1 and the surface 51Ba2. The other regions may also be provided with unevenness that is different from the unevenness of the surface 51Ba1 and the surface 51Ba2.

Additionally, the insulating film 51B is constituted by a single layer of film in the example illustrated in FIG. 11, but the insulating film 51B may have a layered structure in which a plurality of layers of film are layered.

### <Variation 3>

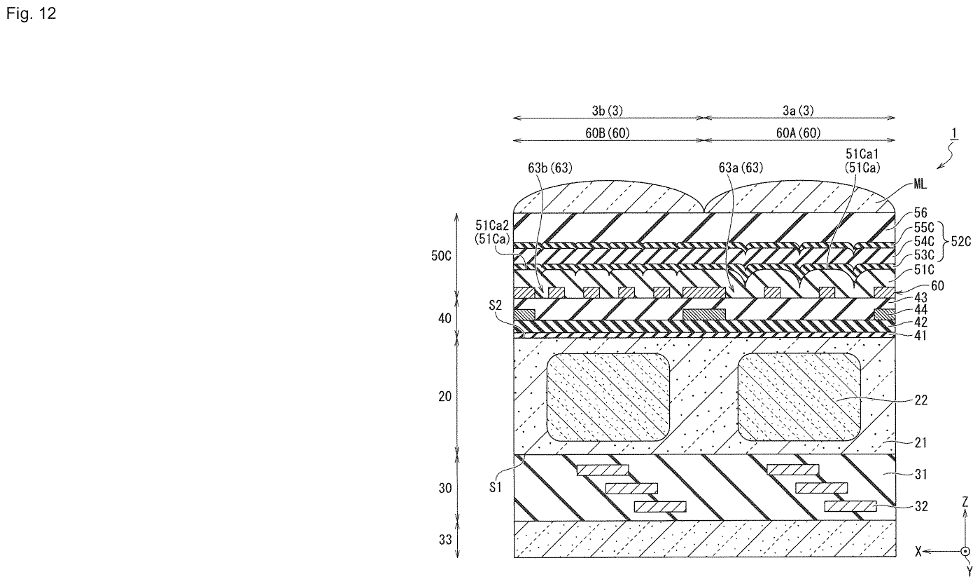

In the light detection device 1 according to Variation 2 on the second embodiment, the unevenness of the surface 51Ba was provided regardless of the positions of the openings 63 in the plasmon filter 60 in plan view, but the present technique is not limited thereto. In Variation 3 on the second embodiment, as illustrated in FIG. 12, recessed parts in the unevenness in an insulating film 51C may be provided in positions that overlap with the openings 63 in the plasmon filter 60 in plan view.

The light detection device 1 according to Variation 3 on the second embodiment has a second insulating layer 50C instead of the second insulating layer 50B. The other configurations of the light detection device 1 are basically the same as in the light detection device 1 of the second embodiment and Variation 2 on the second embodiment described above. Although not limited thereto, the second insulating layer 50C has a layered structure in which, for example, the insulating film 51C, an insulating film 52C, and the flattening film 56, which is an insulating film, are layered in that order. The insulating film 51C constitutes the second insulating film, and the insulating film 52C constitutes the third insulating film.

As already described above, the plasmon filter 60B (a first optical element) selects light of a first wavelength, and the plasmon filter 60A (a second optical element) selects light of a second wavelength longer than the first wavelength. Although not limited thereto, for example, the plasmon filter 60A has the opening array 62a illustrated in FIG. 5, and the plasmon filter 60B has an opening array 62b in which the openings 63 are smaller in size and pitch than the opening array 62a. As illustrated in FIG. 12, in order to distinguish between the openings 63 in the plasmon filter 60A and the openings 63 in the plasmon filter 60B, the openings 63 in the plasmon filter 60A will be called “openings 63a”, and the openings 63 in the plasmon filter 60B will be called “openings 63b”. The openings 63a and the openings 63b will simply be called “openings 63” when not being distinguished from each other. The diameter of the openings 63a in plan view (the horizontal direction) is greater than the diameter of the openings 63b. The first wavelength is, for example, light such as blue or green, and the second wavelength is, for example, light such as red or infrared. It goes without saying that the plasmon filter 60 has other parts that select wavelengths aside from the first wavelength and the second wavelength.

The surface of the insulating film 51C on the insulating film 52C side thereof is called a “surface 51Ca”. Unevenness arising when the insulating film 51C is formed remains in the surface 51Ca. The insulating film 51C covers the plasmon filter 60 so as not to completely fill the openings 63. The parts of the insulating film 51C that overlap with the openings 63 in plan view are recessed into the openings 63. As a result, the surface 51Ca of the parts of the insulating film 51C that overlap with the openings 63 in plan view constitute recessed parts, which are recessed, in the unevenness. In addition, the surface 51Ca of the parts of the insulating film 51C that overlap with the base material 61 in plan view (e.g., between the openings 63) constitute projecting parts, which project, in the unevenness. The unevenness of the surface 51Ca is constituted by such recessed parts and projecting parts. The recessed parts in 51Ca are provided in positions overlapping with the openings 63 in the plasmon filter 60 in plan view. As such, the pitch of the recessed parts in plan view is set to the same pitch as the pitch of the openings 63 in plan view. The height range of the unevenness of the surface 51Ca is set to at least 5 nm and at most 100 nm.

Of the surface 51Ca, a region that overlaps with the plasmon filter 60A in plan view is called a “surface 51Ca1”, and a region that overlaps with the plasmon filter 60B in plan view is called a “surface 51Ca2”. The openings 63a in the plasmon filter 60 provided in positions which overlap with the surface 51Ca1 in plan view are larger in diameter than the openings 63b in the plasmon filter 60 provided in positions which overlap with the surface 51Ca2 in plan view. Among the openings 63a and the openings 63b, the openings 63a, which are the openings with the larger diameter, are less likely to be filled by the insulating film 51C, and the openings 63b, which are the openings with the smaller diameters, are more likely to be filled by the insulating film 51C. Accordingly, the amount by which the surface 51Ca1 is recessed into the openings 63a is greater than the amount by which the surface 51Ca2 is recessed into the openings 63b. In other words, the height range over which the recessed parts are recessed into the surface 51Ca1 is greater than the height range over which the recessed parts are recessed into the surface 51Ca2.

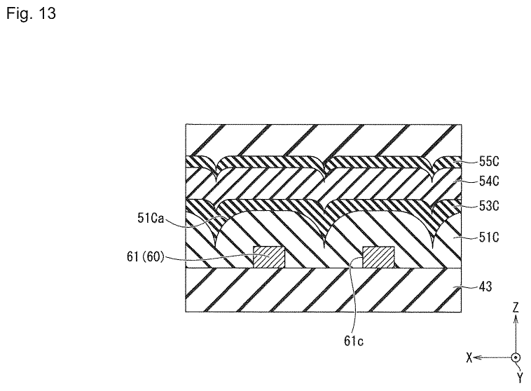

As illustrated in FIG. 13, the side surfaces of the base material 61 that form the openings 63 are called “surfaces 61c”. The degree of the angle of the surfaces 61c with respect to the thickness direction of the semiconductor layer 20 (the Z direction) is ideally 0 degrees. The closer the degree of the angle of the surfaces 61c with respect to the thickness direction is to 0 degrees, the easier the surface 51Ca can be recessed into the openings 63. In actuality, controlling the degree of the angle of the surfaces 61c with respect to the thickness direction to be within 10 degrees makes it easier for the surface 51Ca to be recessed into the openings 63.

It should be noted that the relationship between (i) the height range of the unevenness in the surface 51Ca and the height range of the unevenness in the surface 51Cb and (ii) the height range of the unevenness (surface roughness) in the surface of the film provided between the plasmon filter 60 and the semiconductor layer 20 is the same as in the second embodiment described above.

The insulating film 52C illustrated in FIG. 12 functions as a passivation film, for example. The insulating film 52C has a layered structure in which a film 53C, a film 54C, and a film 55C are layered in that order from the insulating film 51C side. The insulating film 52C, and the film 53C to the film 55C, each constitutes the third insulating film. Although the present embodiment describes an example in which the insulating film 52C has a three-layer layered structure, the layered structure is not limited to the three layers. The insulating film 52C may have a layered structure including two layers, or four or more layers. Additionally, the insulating film 52C may have only one layer of film.

The insulating film 52C is layered on the surface 51Ca of the insulating film 51C. More specifically, the film 53C of the insulating film 52C is layered on the surface 51Ca of the insulating film 51C. The insulating film 51C functions as a base material for the film 53C. The magnitude of the unevenness of the surface of the film 53C on the semiconductor layer 20 side thereof is determined by the unevenness of the base material of the film 53C (the surface 51Ca of the insulating film 51C). The magnitude of the unevenness of the surface of the film 53C on the side opposite from the side on which the base material is located (the microlens ML side) is controlled by the unevenness of the base material and the film forming conditions and film thickness of the film 53C. The film 53C functions as a base material for the film 54C, and the film 54C functions as a base material for the film 55C. In the present embodiment, the film 53C, the film 54C, and the film 55C are layered under conditions which ensure that the surface on the side opposite from the side on which the base material is located is not greatly flattened relative to the unevenness of the base material. As such, the insulating film 52C, and the film 53C to the film 55C, have unevenness that corresponds to the unevenness of the surface 51Ca, on both sides in the thickness direction. As a result, each of the insulating film 52C, and the film 53C to the film 55C, is provided such that the positions of the recessed parts of the unevenness overlap with the openings 63 in the plasmon filter 60 in plan view, and such that the positions of the projecting parts of the unevenness overlap with the parts overlapping with the base material 61 of the plasmon filter 60 in plan view (e.g., between the openings 63).

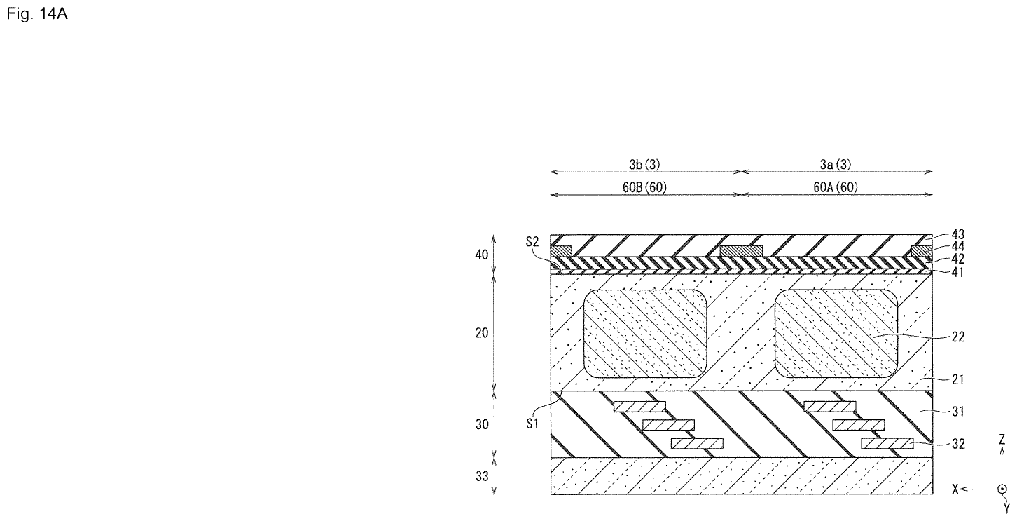

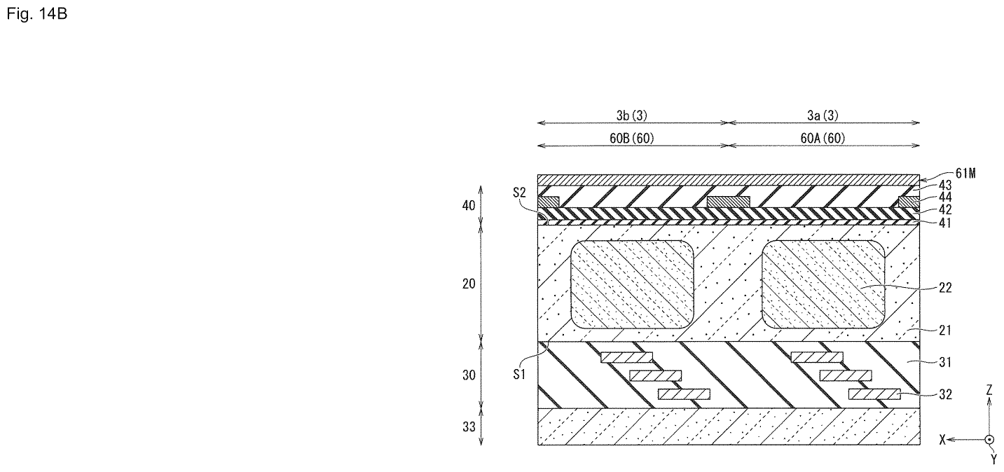

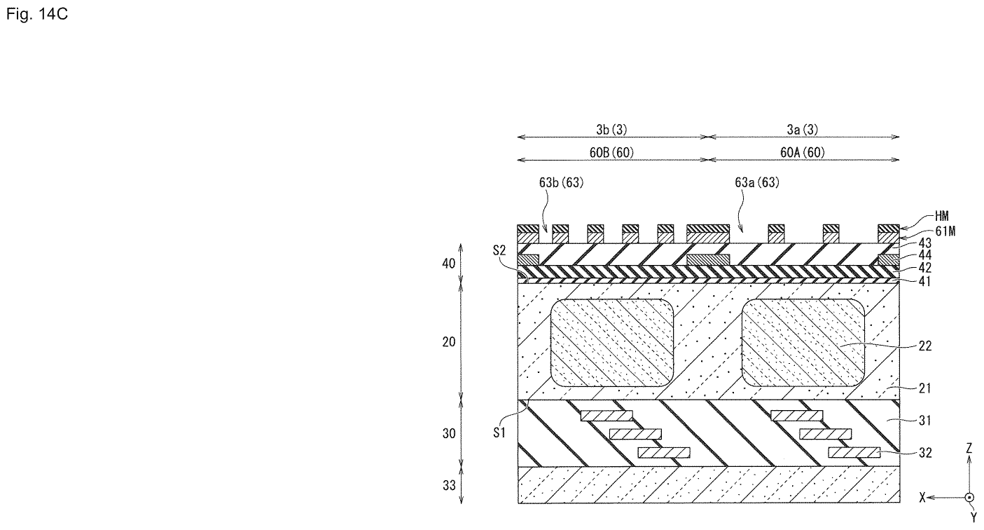

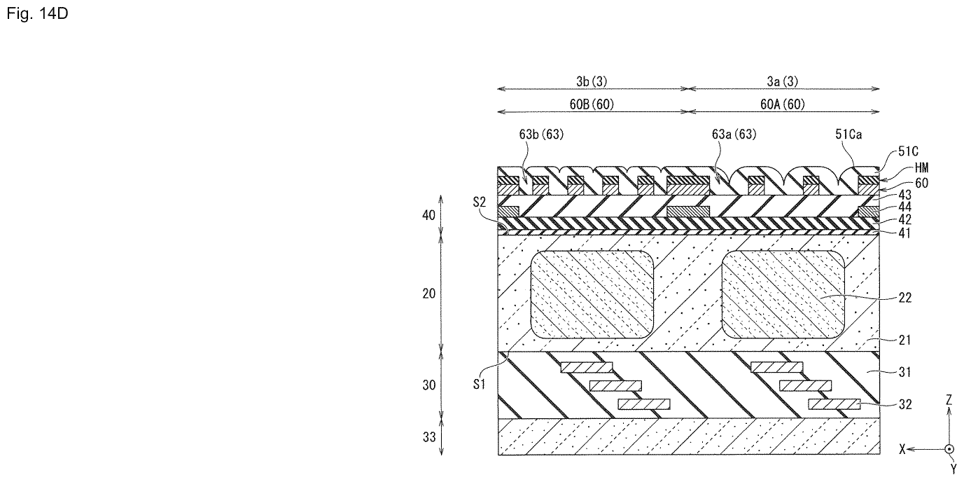

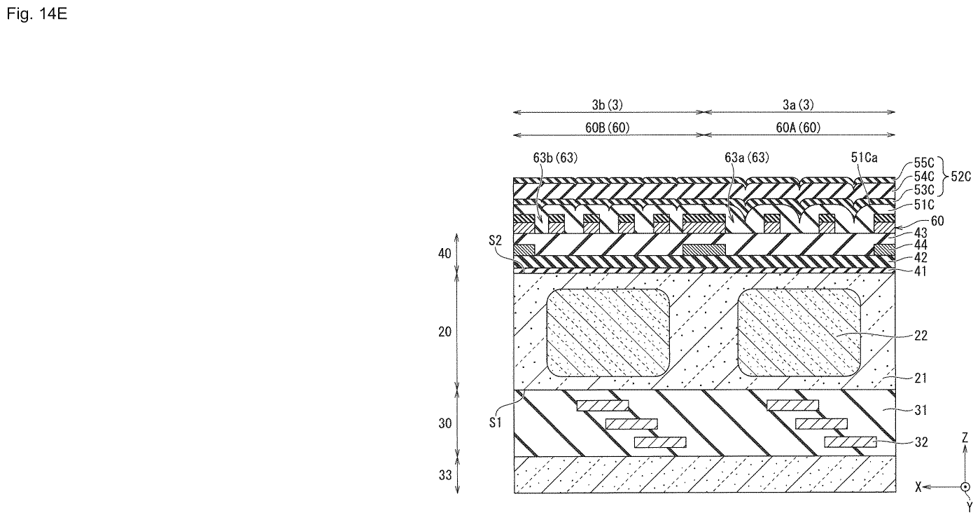

A method for manufacturing the light detection device 1 will be described hereinafter with reference to FIGS. 14A to 14E. First, as illustrated in FIG. 14A, a substrate having the support substrate 33 to the insulating film 43 is prepared using a publicly-known method. More specifically, a substrate including the semiconductor layer 20 in which the photoelectric conversion units is provided, and the first insulating layer 40 layered on the second surface S2 side of the semiconductor layer 20, is prepared. The exposed surface of the insulating film 43 included in the first insulating layer 40 is flattened using a publicly-known method such as chemical mechanical polishing (CMP), for example.

Then, as illustrated in FIG. 14B, a metal film 61M constituting the base material 61 of the plasmon filter 60 is layered on the exposed surface of the insulating film 43 through sputtering, chemical vapor deposition (CVD), or the like. The unevenness may be formed in the exposed surface (the surface 61a) of the layered metal film 61M through dry etching, wet etching, heat treatment, or the like.

Next, as illustrated in FIG. 14C, a hard mask pattern HIM is formed on the exposed surface of the metal film 61M using, for example, a publicly-known film forming technique, lithography technique, etching technique, or the like. Then, the metal film 61M exposed from the openings of the hard mask pattern HM is etched using a publicly-known etching technique. This forms the plurality of openings 63 penetrating the metal film 61M in the thickness direction, and essentially completes the plasmon filter 60. The hard mask pattern HM is constituted by an insulating film. Although not limited thereto, the hard mask pattern HM is constituted by the same material as, for example, the material constituting the insulating film 51C. The thicker the film of the hard mask pattern HM is, the greater the height range will be for the projecting parts in the surface 51Ca of the insulating film 51C.

Then, as illustrated in FIG. 14D, the insulating film 51C is layered so as to cover the hard mask pattern HM and the plasmon filter 60. More specifically, the insulating film 51C is layered so as to cover the hard mask pattern HM but not completely fill the openings 63. The insulating film 51C is layered using, for example, sputtering, CVD, atomic layer deposition (ALD),

or the like. The final magnitude of the unevenness in the surface 51Ca of the insulating film 51C is determined by the method with and conditions under which the insulating film 51C is formed. Accordingly, for example, layering the insulating film 51C under film forming conditions in which the exposed surface has good coverage and the openings 63 are not easily blocked, and making the insulating film 51C as a result, the final unevenness in the surface 51Ca becomes greater. For example, if the unevenness in the surface 51Ca is to be reduced, the insulating film 51C may be formed by selecting film forming conditions in which the openings 63 are easily blocked, or the thickness of the insulating film 51C may be increased.

Then, as illustrated in FIG. 14E, each of the film 53C to the film 55C in the insulating film 52C is formed through sputtering, CVD, ALD, or the like. The magnitude of the unevenness of the surface of the film 53C on the semiconductor layer 20 side thereof is determined by the unevenness of the base material on which the film 53C is layered (the surface 51Ca of the insulating film 51C). The magnitude of the unevenness of the surface of the film 53C on the side opposite from the side on which the base material is located (the microlens ML side) is controlled by the unevenness of the base material and the film forming conditions and film thickness of the film 53C. The film 53C functions as a base material for the film 54C, and the film 54C functions as a base material for the film 55C. Then, the film 53C, the film 54C, and the film 55C are layered under conditions which ensure that the surface on the side opposite from the side on which the base material is located is not greatly flattened relative to the unevenness of the base material. The subsequent processes may be carried out through a publicly-known method, and will therefore not be described here.

The light detection device 1 according to Variation 3 on the second embodiment provides effects similar to those of the light detection device 1 according to the second embodiment described above. Additionally, the light detection device 1 according to Variation 3 on the second embodiment provides effects similar to those of the light detection device 1 according to Variation 2 on the second embodiment described above.

In the light detection device 1 according to Variation 3 on the second embodiment, there is no need for a dedicated process for forming unevenness in the surface 51Ca, which makes it possible to suppress the manufacturing costs.

In the light detection device 1 according to Variation 3 on the second embodiment, both the unevenness in the surface 51Ca1 and the unevenness in the surface 51Ca2, which differ in magnitude from each other, can be formed at the same time in the same process. Accordingly, it is not necessary to repeat the same process for each magnitude of unevenness, which makes it possible to suppress the manufacturing cost.

Additionally, the insulating film 51C is constituted by a single layer of film in the example illustrated in FIG. 12, but the insulating film 51C may have a layered structure in which a plurality of layers of film are layered.

### Application Example

### <1. Example of Application to Electronic Device>

An example in which the present technique is applied to an electronic device 100, illustrated in FIG. 15, will be described next. The electronic device 100 includes a solid-state image capturing device 101, the optical lens 102, a shutter device 103, a driving circuit 104, and a signal processing circuit 105. Although not limited thereto, the electronic device 100 is an electronic device such as a camera or the like, for example. The electronic device 100 includes the light detection device 1 described above as the solid-state image capturing device 101.

The optical lens (optical system) 102 forms an image of image light (incident light 106) from a subject on the image capturing plane of the solid-state image capturing device 101. As a result, signal charges are accumulated in the solid-state image capturing device 101 over a set period. The shutter device 103 controls a light emission period and a light shielding period for the solid-state image capturing device 101. The driving circuit 104 supplies a drive signal for controlling a transfer operation of the solid-state image capturing device 101 and a shutter operation of the shutter device 103. An operation of transferring a signal to the solid-state image capturing device 101 is performed according to the drive signal (timing signal) supplied from the driving circuit 104. The signal processing circuit 105 performs various types of signal processing on signals (pixel signals) output from the solid-state image capturing device 101. A video signal having been subjected to the signal processing is stored in a storage medium such as a memory or output to a monitor.

According to this configuration, the electronic device 100 can suppress light interference and flare in the solid-state image capturing device 101, which makes it possible to improve the image quality of the video signal.

The electronic device 100 is not limited to a camera, and may be another electronic device. For example, the electronic device may be an image capturing device such as a camera module for a mobile device such as a mobile phone.

In addition, the electronic device 100 may include, as the solid-state image capturing device 101, the light detection device 1 according to any of the first embodiment, the second embodiment, and the variations on those embodiments, or the light detection device 1 according to a combination of at least two of the first embodiment, the second embodiment, and the variations on those embodiments.

### Other Embodiments

Although the present technique has been described according to the first embodiment and the second embodiment, it is to be understood that the descriptions and drawings constituting this disclosure are not intended to limit the present technique. Various alternative embodiments, working examples, and operational techniques should be clear to a person skilled in the art based on this disclosure.

For example, the technical spirit of the first embodiment and the second embodiment can be combined with each other. For example, various combinations in accordance with the technical spirit are possible, such as the light detection device 1 according to the second embodiment described above and variations thereon including the wire grid polarizer 60 described in Variation 1 on the first embodiment in place of the plasmon filter 60.

In addition to solid-state image capturing devices serving as image sensors as described above, the present technique can be applied in all types of light detection devices, including range sensors which measure distances, known as time of flight (ToF) sensors, and the like. A range sensor is a sensor that emits irradiated light toward an object, detects reflected light which returns when the irradiated light is reflected by a surface of the object, and calculates a distance to the object based on a time of flight from when the irradiated light is emitted to when the reflected light is received. The structure having the unevenness described above can be employed as the structure of the range sensor.

The light detection device 1 may also be a layered CMOS image sensor (CIS) in which two or more semiconductor substrates are layered. In that case, at least one of the logic circuitry 13 and the readout circuit 15 may be provided on a substrate different from the semiconductor substrate on which the photoelectric conversion units of the semiconductor substrate is provided.

Additionally, for example, the materials listed as constituting the constituent elements described above may include additives, impurities, or the like.

In this manner, it goes without saying that the present technique includes various embodiments and the like not described herein. Accordingly, the technical scope of the present technique is to be defined only by the invention defining matters denoted in the scope of claims pursuant to the above descriptions.

Furthermore, the effects described in the present specification are merely exemplary and not intended to be limiting, and other effects may be provided as well.

The present technique may be configured as follows.

(1)

A light detection device including:
a semiconductor layer having a photoelectric conversion unit;
a first insulating film layered on a light incidence surface side of the semiconductor layer;
an optical element having a metal film layered on the first insulating film and an opening array formed in a region, of the metal film, that overlaps with the photoelectric conversion unit in plan view, the optical element being capable of selecting a specific light;
a second insulating film layered on the optical element; and
a third insulating film layered on the second insulating film,
wherein one of a surface of the metal film on the second insulating film side thereof or a surface of the second insulating film on the third insulating film side thereof has unevenness that is greater than unevenness in a surface of the metal film on the first insulating film side thereof or a surface of the first insulating film on the semiconductor layer side thereof.
   (2)

The light detection device according to (1),
wherein the semiconductor layer has a plurality of the photoelectric conversion units disposed in a two-dimensional array in plan view,
the optical element includes a first optical element that selects a first wavelength and a second optical element that selects a second wavelength longer than the first wavelength, and
of the surface of the second insulating film on the third insulating film side thereof, the unevenness in a region that overlaps with the second optical element in plan view is greater than the unevenness in a region that overlaps with the first optical element in plan view.
   (3)

The light detection device according to (2),
wherein the opening array is an array of a plurality of openings, and
in the surface of the second insulating film on the third insulating film thereof, parts that overlap with the openings in plan view constitute recessed parts of the unevenness, and parts that overlap with the metal film constitute projecting parts of the unevenness.
   (4)

The light detection device according to (3),
wherein the size of an angle of a side surface of the metal film forming the openings with respect to the thickness direction of the semiconductor layer is no greater than 10 degrees.
   (5)

The light detection device according to any one of (1) to (4),
wherein both surfaces of the third insulating film in the thickness direction have unevenness that follows the unevenness in the surface of the second insulating film on the third insulating film side thereof.
   (6)

The light detection device according to any one of (1) to (5),
wherein both of a surface of the metal film on the second insulating film side thereof and a surface of the second insulating film on the third insulating film side thereof have unevenness that is greater than unevenness in a surface of the metal film on the first insulating film side thereof or a surface of the first insulating film on the semiconductor layer side thereof.
   (7)

The light detection device according to any one of (1) to (6),
wherein the optical element is a color filter that utilizes surface plasmon resonance.
   (8)

The light detection device according to any one of (1) to (6),
wherein the optical element is a wire grid polarizer.
   (6)

A method for manufacturing a light detection device, the method comprising: preparing a substrate including a semiconductor layer in which a photoelectric conversion unit is provided and a first insulating film layered on a light incidence surface side of the semiconductor layer;

layering a metal film on an exposed surface of the first insulating film;

forming a hard mask pattern on an exposed surface of the metal film;

forming a plurality of openings in the metal film by etching the metal film based on the hard mask pattern, to form an optical element having the metal film and an array of the openings; and
layering a second insulating film to cover the hard mask pattern but not completely fill the openings.
   (10)

An electronic device comprising:
a light detection device and an optical system that causes the light detection device to form an image of image light from a subject,
wherein the light detection device includes:
a semiconductor layer having a photoelectric conversion unit;
a first insulating film layered on a light incidence surface side of the semiconductor layer;
an optical element having a metal film layered on the first insulating film and an opening array formed in a region, of the metal film, that overlaps with the photoelectric conversion unit in plan view, the optical element being capable of selecting a specific light;
a second insulating film layered on the optical element; and
a third insulating film layered on the second insulating film,
wherein one of a surface of the metal film on the second insulating film side thereof or a surface of the second insulating film on the third insulating film side thereof has unevenness that is greater than unevenness in a surface of the metal film on the first insulating film side thereof or a surface of the first insulating film on the semiconductor layer side thereof.

The scope of the present technique is not limited to the exemplary embodiments illustrated in the drawings and described above, and includes all embodiments which have the object of the present technique and provide equivalent effects. Furthermore, the scope of the present technique is not limited to the combinations of features of the invention defined by the claims, and can be defined by all desired combinations of specific features among all the features disclosed.

### REFERENCE SIGNS LIST

1 Light detection device
2 Semiconductor chip
3, 3a, 3b Pixel
4 Vertical drive circuit
5 Column signal processing circuit
6 Horizontal drive circuit
7 Output circuit
8 Control circuit
10 Pixel drive line
11 Vertical signal line
12 Horizontal signal line
14 Bonding pad
20 Semiconductor layer
22 Semiconductor region (photoelectric conversion unit)
30 Wiring layer
40 First insulating layer
41 Pinning layer
42, 43 Insulating film
44 Light shielding layer
50, 50A, 50B, 50C Second insulating layer
51, 51A, 51B, 51C Insulating film
52, 52A, 52B, 52C Insulating film
53, 53A, 53B, 53C Film
54, 54A, 54B, 54C Film
55, 55A, 55B, 55C Film
56 Flattening film
57 Holes
57A Groove
60, 60A, 60B Plasmon filter
60a Opening region
60b Frame region
61 Base material
61a, 61b, 61c Surface
61M Metal film
62 Opening array
63, 63a, 63b Opening
100 Electronic device
101 Solid-state image capturing device
102 Optical system (optical lens)
103 Shutter device
104 Drive circuit
105 Signal processing circuit
d1, d2 Distance
HM Hard mask pattern

1. A light detection device comprising:
a semiconductor layer having a photoelectric conversion unit;
a first insulating film layered on a light incidence surface side of the semiconductor layer;
an optical element having a metal film layered on the first insulating film and an opening array formed in a region, of the metal film, that overlaps with the photoelectric conversion unit in plan view, the optical element being capable of selecting a specific light;
a second insulating film layered on the optical element; and
a third insulating film layered on the second insulating film,
wherein one of a surface of the metal film on the second insulating film side thereof or a surface of the second insulating film on the third insulating film side thereof has unevenness that is greater than unevenness in a surface of the metal film on the first insulating film side thereof or a surface of the first insulating film on the semiconductor layer side thereof.

2. The light detection device according to claim 1,
wherein the semiconductor layer has a plurality of the photoelectric conversion units disposed in a two-dimensional array in plan view,
the optical element includes a first optical element that selects a first wavelength and a second optical element that selects a second wavelength longer than the first wavelength, and
of the surface of the second insulating film on the third insulating film side thereof, the unevenness in a region that overlaps with the second optical element in plan view is greater than the unevenness in a region that overlaps with the first optical element in plan view.

3. The light detection device according to claim 2,
wherein the opening array is an array of a plurality of openings, and
in the surface of the second insulating film on the third insulating film thereof, parts that overlap with the openings in plan view constitute recessed parts of the unevenness, and parts that overlap with the metal film constitute projecting parts of the unevenness.

4. The light detection device according to claim 3,
wherein the size of an angle of a side surface of the metal film forming the openings with respect to the thickness direction of the semiconductor layer is no greater than 10 degrees.

5. The light detection device according to claim 1,
wherein both surfaces of the third insulating film in the thickness direction have unevenness that follows the unevenness in the surface of the second insulating film on the third insulating film side thereof.

6. The light detection device according to claim 1,
wherein both of a surface of the metal film on the second insulating film side thereof and a surface of the second insulating film on the third insulating film side thereof have unevenness that is greater than unevenness in a surface of the metal film on the first insulating film side thereof or a surface of the first insulating film on the semiconductor layer side thereof.

7. The light detection device according to claim 1,
wherein the optical element is a color filter that utilizes surface plasmon resonance.

8. The light detection device according to claim 1,
wherein the optical element is a wire grid polarizer.

9. A method for manufacturing a light detection device, the method comprising:
preparing a substrate including a semiconductor layer in which a photoelectric conversion unit is provided and a first insulating film layered on a light incidence surface side of the semiconductor layer;
layering a metal film on an exposed surface of the first insulating film;
forming a hard mask pattern on an exposed surface of the metal film;
forming a plurality of openings in the metal film by etching the metal film based on the hard mask pattern, to form an optical element having the metal film and an array of the openings; and
layering a second insulating film to cover the hard mask pattern but not completely fill the openings.

10. An electronic device comprising:
a light detection device and an optical system that causes the light detection device to form an image of image light from a subject,
wherein the light detection device includes:
a semiconductor layer having a photoelectric conversion unit;
a first insulating film layered on a light incidence surface side of the semiconductor layer;
an optical element having a metal film layered on the first insulating film and an opening array formed in a region, of the metal film, that overlaps with the photoelectric conversion unit in plan view, the optical element being capable of selecting a specific light;
a second insulating film layered on the optical element; and
a third insulating film layered on the second insulating film, and
wherein one of a surface of the metal film on the second insulating film side thereof or a surface of the second insulating film on the third insulating film side thereof has unevenness that is greater than unevenness in a surface of the metal film on the first insulating film side thereof or a surface of the first insulating film on the semiconductor layer side thereof.
